(19) United States
(12) Patent Application Publication
(10) Pub. No.: US 2008/0036080 A1
(43) Pub. Date: Feb. 14, 2008

(54) CHIP PACKAGE

(75) Inventor: Chia-Hsu Lin, Taipei City (TW)

Correspondence Address: J C PATENTS, INC., 4 VENTURE, SUITE 250, IRVINE, CA, 92618, US

(73) Assignee: ADVANCED SEMICONDUCTOR ENGINEERING, INC., Kaohsiung (TW)

(21) Appl. No.: 11/828,521

(22) Filed: Jul. 26, 2007

(30) Foreign Application Priority Data
Aug. 11, 2006 (TW) 95129657

(51) Int. Cl. H01L 23/48

(52) U.S. Cl. 257/737; 257/E23.01

(57) ABSTRACT

A chip package with an anti-creeping underfill is provided. The chip package includes a carrier, a chip and an underfill. The chip is disposed on the carrier and includes a chip body and a blocking portion. The chip body has at least one lateral surface and the blocking portion is formed on the lateral surface. The blocking portion has a top surface and a bottom surface. The top surface and the bottom surface form an acute angle. The underfill is formed between the carrier and the chip and blocked by the blocking portion to prevent creeping.

### CROSS-REFERENCE TO RELATED APPLICATION

This application claims the priority benefit of Taiwan application serial no. 95129657, filed on Aug. 11, 2006. All disclosure of the Taiwan application is incorporated herein by reference.

### BACKGROUND OF THE INVENTION

1. Field of the Invention

The present invention generally relates to a chip package, more particularly, to a chip package with an anti-creeping underfill.

2. Description of Related Art

To shorten the transmission distance of electrical signals between a chip and a carrier and reduce the size of a chip package, the chip is flip-chip bonded to the carrier. As shown in FIG. 1, a conventional chip package 100 includes a carrier 110, a chip 120 and an underfill 130. A plurality of connection pads 112 are formed on a surface 111 of the carrier 110. The chip 120 is flip-chip bonded to the surface 111 of the carrier 110. The chip 120 has an active surface 121 and a back surface 122. The active surface 121 of the chip 120 has a plurality of bonding pads 123. A plurality of bumps 140 connect the connection pads 112 of the carrier 110 with the bonding pads 123 of the chip 120. The underfill 130 is formed between the carrier 110 and the chip 120 to protect the bumps 140. However, in a subsequent baking process of the underfill 130, the viscosity of the underfill 130 is lowered, and the underfill 130 may creep along the lateral surface of the chip 120 to the back surface 122 and lead to contamination.

### SUMMARY OF THE INVENTION

Accordingly, the present invention is directed to a chip package with an anti-creeping underfill. A chip having a chip body and a blocking portion is disposed on a carrier. The blocking portion is formed on a lateral surface of the chip body. The blocking portion has a top surface and a bottom surface and the top surface and the bottom surface form an acute angle. An underfill is formed between the chip and the carrier and is blocked by the blocking portion at the bottom surface to prevent the underfill from creeping along the lateral surface of the chip to contaminate the chip.

According to an embodiment of the present invention, a chip package with an anti-creeping underfill is provided. The chip package mainly includes a carrier, a chip and an underfill. The chip is disposed on the carrier and includes a chip body and a blocking portion. The chip body has an active surface, a back surface and a lateral surface. The blocking portion is formed on the lateral surface of the chip body. The blocking portion has a top surface and a bottom surface and the top surface and the bottom surface form an acute angle. The underfill is formed between the carrier and the chip and is blocked by the blocking portion at the bottom surface.

In order to make the aforementioned and other objects, features and advantages of the present invention comprehensible, preferred embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a conventional chip package.

FIG. 2 is a schematic cross-sectional view of a chip package with an anti-creeping underfill according to a first embodiment of the present invention.

FIG. 3 is a top view of a wafer before cutting according to a first embodiment of the present invention.

FIGS. 4A to 4C are schematic cross-sectional views showing a cutting process of a wafer with an anti-creeping underfill according to a first embodiment of the present invention.

FIGS. 5A to 5D are schematic cross-sectional views showing another cutting process of a wafer with an anti-creeping underfill according to a first embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

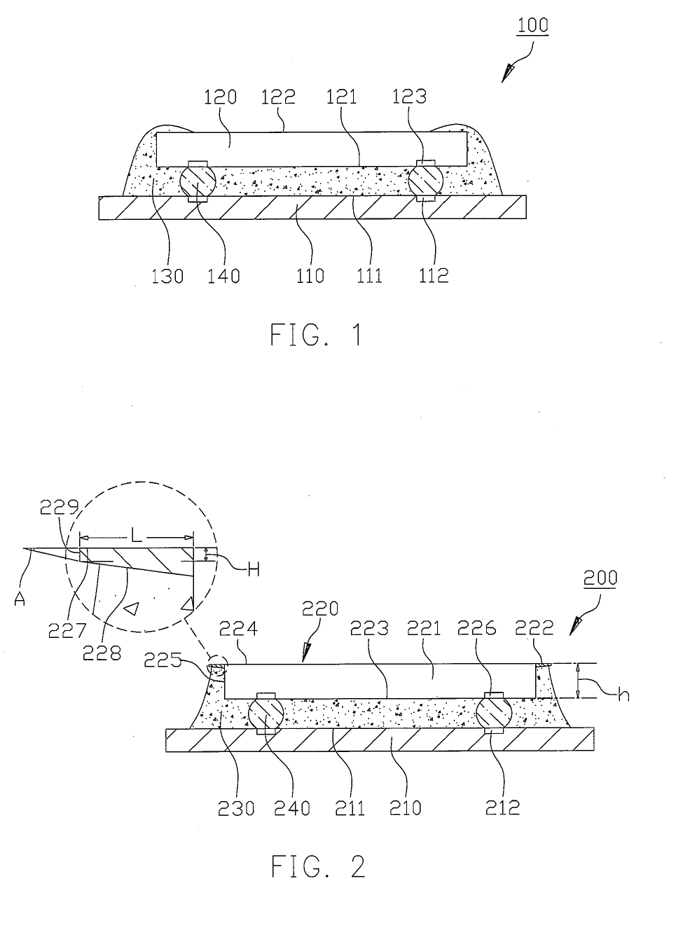

FIG. 2 is a schematic cross-sectional view of a chip package 200 with an anti-creeping underfill according to an embodiment of the present invention. As shown in FIG. 2, the chip package 200 includes a carrier 210, a chip 220 and an underfill 230. The carrier 210 has a surface 211. A plurality of connection pads 212 are formed on the surface 211. The chip 220 is disposed on the surface 211 of the carrier 210 and is electrically connected to the carrier 210. The chip 220 includes a chip body 221 and a blocking portion 222. The chip body has an active surface 228, a back surface 224 and at least one lateral surface 225 between the active surface 223 and the back surface 224. A plurality of bonding pads 226 are formed on the active surface 223. In addition, the chip 220 includes a plurality of bumps 240. These bumps 240 are disposed on the bonding pads 226 of the active surface 223. The active surface 223 of the chip body 221 faces the surface 211 of the carrier 210 and the bumps 240 are bonded to the corresponding connection pads 212 of the carrier 210. The blocking portion 222 may be formed on the lateral surface 225 of the chip body 221 as an integral unit. In the present embodiment, the blocking portion 222 has a top surface 227, a bottom surface 228 and a sidewall 229 between the top surface 227 and the bottom surface 228. The extension of the top surface 227 and the bottom surface 228 form an included angle A, which is an acute angle. The top surface 227 of the blocking portion 222 may be co-planar with the back surface 224 of the chip body 221. Alternatively, in another embodiment, the top surface 227 of the blocking portion 222 is parallel to the back surface 224 of the chip body 221. The bottom surface 228 of the blocking portion 222 may be an inclined surface or an arc-shaped surface. In the present embodiment, the bottom surface 228 is an inclined surface. The sidewall 229 of the blocking portion 222 has a height H not greater than half the thickness h of the chip body 221. Width L of the top surface 227 is not smaller than 5 μm. The underfill 230 is formed between the carrier 210 and the chip 220 and is blocked by the blocking portion 222 below the bottom surface 228. The blocking portion 222 of the chip 220 may prevent the underfill 230 from creeping over and contaminating the chip 220.

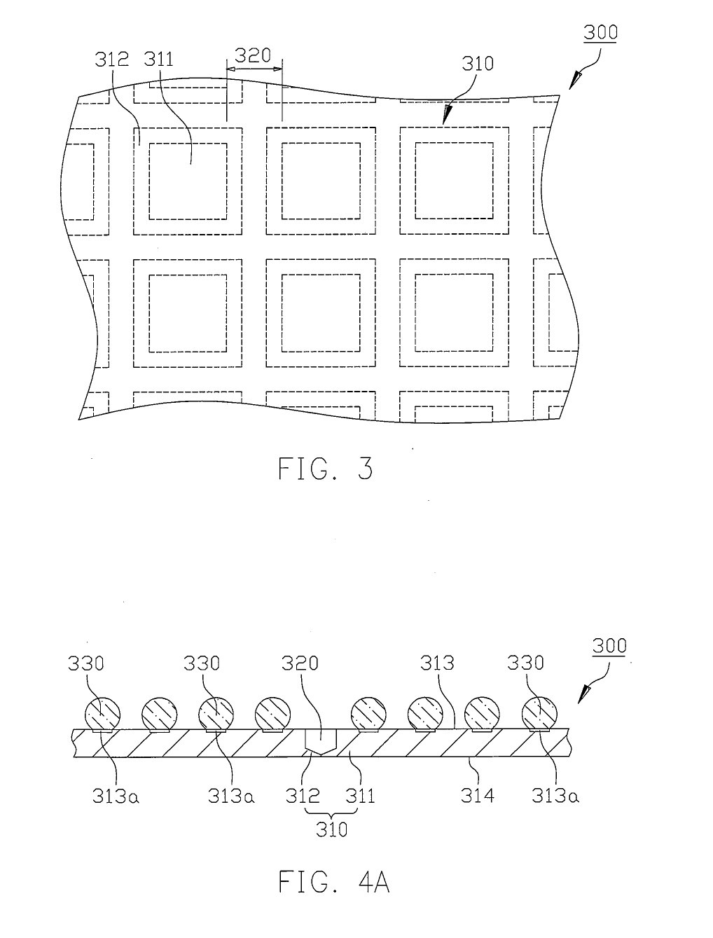

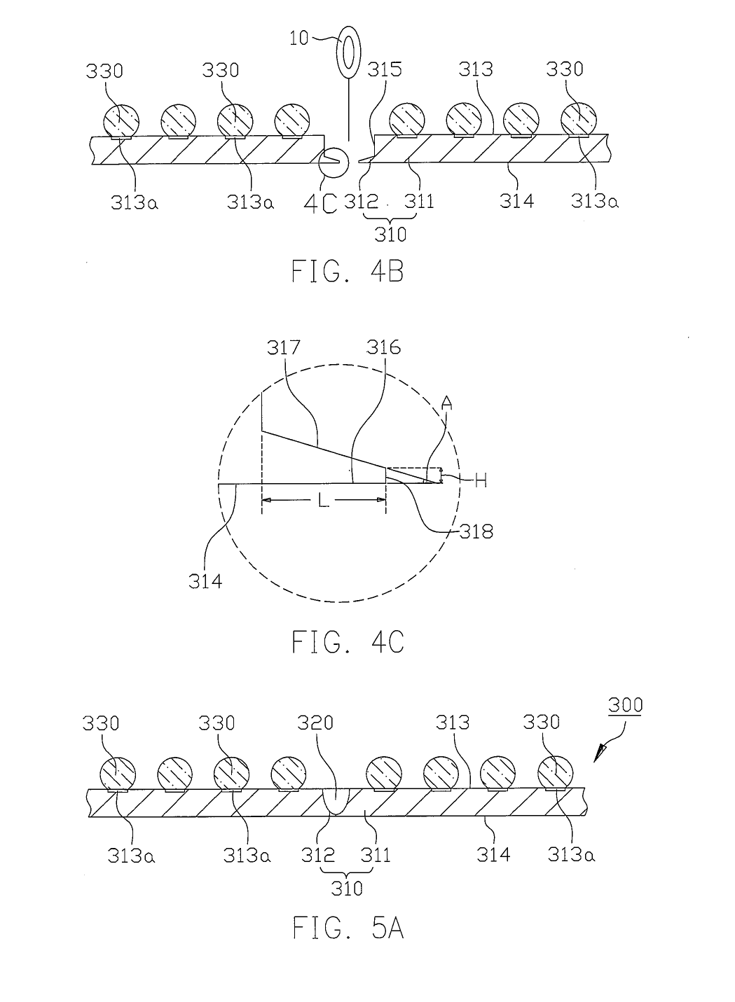

FIG. 3 is a top view of a wafer before cutting and FIGS. 4A to 4C are schematic cross-sectional views showing a cutting process of a wafer with an anti-creeping underfill according to an embodiment of the present invention. First, as shown in FIGS. 3 and 4A, a wafer 300 having a plurality of chips 310 and a plurality of cutting areas 320 defined between the chips 310 is provided. Each chip 310 includes a chip body 311 and a blocking portion 312. The chip body 311 has an active surface 313, a back surface 314 and a lateral surface 315. The active surface 313 has a plurality of bonding pads 313a formed thereon. A plurality of bumps 330 may be disposed on the boding pads 313a. Next, as shown in FIG. 4B, the wafer 300 is cut along the cutting areas 320 to separate the chips 310. In the present embodiment, the chips 310 are cut by using a cutting tool 10 in a once-cutting process. Thereafter, as shown in FIG. 4C, the blocking portion 312 has a top surface 316, a bottom surface 317 and a sidewall 318 between the top surface 316 and the bottom surface 317 after cutting. An extension of the top surface 316 and the bottom surface 317 form an included angle A, which is an acute angle. In the present embodiment, the bottom surface 317 of the blocking portion 312 is an inclined surface, and the top surface 316 of the blocking portion 312 is co-planar with the back surface 314 of the chip body 311. In addition, the height H of the sidewall 318 of the blocking portion 312 is not greater than half the height h of the chip body 311, and the width L of the top surface 316 is not smaller than 5 μm.

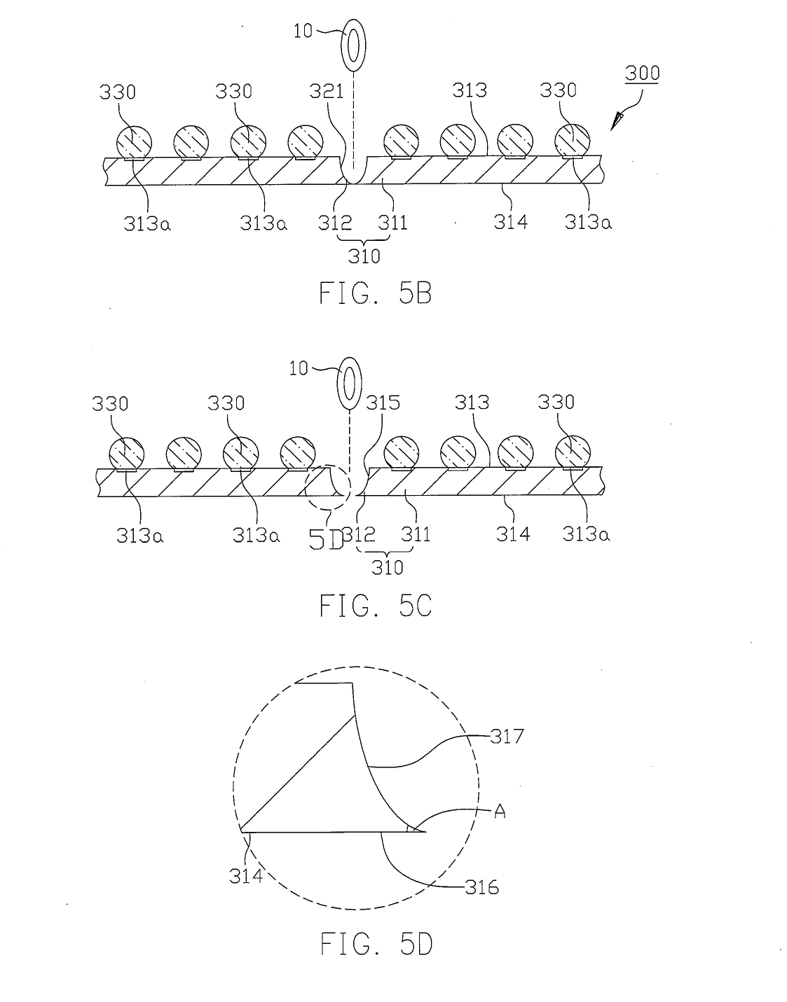

Alternatively, the chips 310 may be cut by using a twice-cutting process with different cutting tools 10. FIGS. 5A to 5C are schematic cross-sectional views showing a cutting process of a wafer with an anti-creeping underfill according to an embodiment of the present invention. First, as shown in FIG. 5A, a wafer 300 having a plurality of chips 310 and a plurality of cutting areas 320 defined between the chips 310 is provided. Each chip 310 includes a chip body 311 and a blocking portion 312. The chip body 311 has an active surface 313, a back surface 314 and a lateral surface 315. The active surface 313 has a plurality of bonding pads 313a formed thereon, and a plurality of bumps 330 are disposed on the bonding pads 313a, respectively. Next, as shown in FIG. 5B, the chips 310 are formed by a twice-cutting process in the present embodiment. In the first cutting process, the cutting tool 10 cuts along the cutting areas 320 so as to form a plurality of arc-shape grooves 321 in the cutting areas 320 of the wafer 300. Next, as shown in FIG. 5C, a second cutting process is performed along these arc-shape grooves 321 so as to separate the chips 310. Thereafter, as shown in FIG. 5D, the blocking portion 312 of the chip 310 having a top surface 316 and a bottom surface 317 is formed after the second cutting process. An included angle A, which is an acute angle, is formed between the top surface 316 and the bottom surface 317. The top surface 316 of the blocking portion 312 is co-planar with the back surface 314 of the chip body 311. In the present embodiment, the bottom surface 317 is an arc-shaped surface.

It will be apparent to those skilled in the art that various modifications and variations may be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A chip package, comprising:
a carrier with a surface;
a chip, disposed on the carrier, and comprising:
a chip body, having an active surface, a back surface and a lateral surface; and
a blocking portion, formed on the lateral surface of the chip, wherein the blocking portion has a top surface and a bottom surface, and an acute angle is formed between the top surface and the bottom surface; and
an underfill, formed between the carrier and the chip and blocked by the bottom surface of the blocking portion.

2. The chip package according to claim 1, wherein the chip further comprises a plurality of bumps disposed on the active surface.

3. The chip package according to claim 2, wherein the active surface of the chip body faces the surface of the carrier, and the chip is bonded with the carrier through the bumps.

4. The chip package according to claim 1, wherein the top surface of the blocking portion is co-planar with the back surface of the chip body.

5. The chip package according to claim 1, wherein the bottom surface of the blocking portion is an inclined surface.

6. The chip package according to claim 1, wherein the bottom surface of the blocking portion is an arc-shaped surface.

7. The chip package according to claim 1, wherein the blocking portion has a sidewall between the top surface and the bottom surface.

8. The chip package according to claim 7, wherein a height of the sidewall is not greater than half of a thickness of the chip body.

9. The chip package according to claim 1, wherein a width of the top surface is not smaller than 5 μm.

10. A chip structure, comprising:
a chip body, having an active surface, a back surface and at least one lateral surface; and
a blocking portion, formed on the lateral surface of the chip body, wherein the blocking portion has a top surface and a bottom surface, and the top surface and the bottom surface form an acute angle.

11. The chip structure according to claim 10, further comprising a plurality of bumps disposed on the active surface.

12. The chip structure according to claim 10, wherein the top surface of the blocking portion is co-planar with the back surface of the chip body.

13. The chip structure according to claim 10, wherein the bottom surface of the blocking portion is an inclined surface.

14. The chip structure according to claim 10, wherein the bottom surface of the blocking portion is an arc-shaped surface.

15. The chip structure according to claim 10, wherein the blocking portion has a sidewall between the top surface and the bottom surface.

16. The chip structure according to claim 15, wherein a height of the sidewall is not greater than half of a thickness of the chip body.

17. The chip structure according to claim 10, wherein a width of the top surface is not smaller than 5 μm.
